(19) United States
(12) Patent Application Publication
(10) Pub. No.: US 2026/0301837 A1
(43) Pub. Date: Oct. 1, 2026

(54) FAILURE BITS DETECTION CIRCUIT, FAILURE BITS DETECTION CIRCUIT METHOD, AND MEMORY DEVICE

(71) Applicant: MACRONIX International Co., Ltd., Hsinchu (TW)

(72) Inventors: Chung-Han Wu, Kaohsiung City (TW); Che-Wei Liang, Hsinchu County (TW); Chih-He Chiang, Hsinchu County (TW); Shang-Chi Yang, Changhua County (TW)

(73) Assignee: MACRONIX International Co., Ltd., Hsinchu (TW)

(21) Appl. No.: 19/091,828

(22) Filed: Mar. 27, 2025

(51) Int. Cl. G11C 29/12

(52) U.S. Cl. CPC G11C 29/12005

(57) ABSTRACT

A failure bits detection circuit, a failure bits detection circuit method, and a memory device are provided herein. A current mirror includes a first end coupled to a page buffer of a memory device and a second end coupled to a criteria generator, and mirrors a sensing current at the first end to generate a criteria current at the second end during a read mode. The criteria generator provides a criteria load between the second end and a reference ground end according to a criteria code. A comparator compares a first voltage at a first input end of the comparator with a second voltage at a second input end of the comparator to generate a detection result at the output end for determining a failure bits number of the memory device. In this manner, a 3D NAND flash memory with high capacity and high performance is achieved.

### BACKGROUND

### Technical Field

The disclosure relates to a failure bits detection circuit; particularly, the disclosure relates to a failure bits detection circuit, a failure bits detection circuit method, and a memory device.

### Description of Related Art

With the advancement of technology, memory devices are often constructed by stacking multiple layers of memory cells to increase the density of the memory cells. In the case of a large increase in the number of memory cells, a failure bits detection mechanism for the memory cells becomes an important element.

### SUMMARY

The disclosure is direct to a failure bits detection circuit method, and a memory device, so as to improve accuracy and speed of a failure bits detection of a memory device.

In this disclosure, a failure bits detection circuit is provided. The failure bits detection circuit includes a current mirror, a criteria generator, and a comparator. The current mirror includes a first end coupled to a page buffer of a memory device and a second end coupled to a criteria generator, and is configured to mirror a sensing current at the first end of the current mirror to generate a criteria current at the second end of the current mirror during a read mode of the memory device. The criteria generator is configured to provide a criteria load between the second end of the current mirror and a reference ground end according to a criteria code. The comparator includes a first input end coupled to the first end of the current mirror, a second input end coupled to the second end of the current mirror, and an output end. The criteria generator is configured to compare a first voltage at the first input end with a second voltage at the second input end to generate a detection result at the output end for determining a failure bits number of the memory device.

In this disclosure, a failure bits detection method is provided. The failure bits detection method includes following steps: mirroring a sensing current at a first end of a current mirror to generate a criteria current at a second end of the current mirror during a read mode of a memory device, wherein the first end of the current mirror is coupled to a page buffer of the memory device and the second end of the current mirror is coupled to a criteria generator; and providing a criteria load between the second end of the current mirror and a reference ground end according to a criteria code; and comparing a first voltage at a first input end of a comparator with a second voltage at a second input end of the comparator to generate a detection result for determining a failure bits number of the memory device.

In this disclosure, a memory device is provided. The memory device includes a plurality of segments of memory cells and a plurality of failure bits detection circuits. Each of the plurality of segments includes a page buffer. Each of the plurality of failure bits detection circuits is coupled to the page buffer, respectively. Each of the plurality of failure bits detection circuits includes a current mirror, a criteria generator, and a comparator. The current mirror includes a first end coupled to the page buffer of the memory device and a second end coupled to a criteria generator, and is configured to mirror a sensing current at the first end of the current mirror to generate a criteria current at the second end of the current mirror during a read mode of the memory device. The criteria generator is configured to provide a criteria load between the second end of the current mirror and a reference ground end according to a criteria code. The comparator includes a first input end coupled to the first end of the current mirror, a second input end coupled to the second end of the current mirror, and an output end. The criteria generator is configured to compare a first voltage at the first input end with a second voltage at the second input end to generate a detection result at the output end for determining a failure bits number of the memory device.

Based on the above, according to the failure bits detection circuit, the failure bits detection circuit method, and the memory device, the accuracy of the failure bits detection is improved and high speed performance without extra timing overhead is achieved.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of a memory device according to an embodiment of the disclosure.

FIG. 2 is a schematic diagram of a memory device according to an embodiment of the disclosure.

FIG. 3 is a schematic timing chart of a memory device according to an embodiment of the disclosure.

FIG. 4 is a schematic diagram of a memory device according to an embodiment of the disclosure.

FIG. 5 is a schematic flowchart of a failure bits detection method according to an embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as "comprise" and "include" are open-ended terms, and should be explained as "including but not limited to...".

The term “coupling (or connection)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

It should be noted that in the following embodiments, the technical features of several different embodiments may be replaced, recombined, and mixed without departing from the spirit of the disclosure to complete other embodiments. As long as the features of each embodiment do not violate the spirit of the disclosure or conflict with each other, they may be mixed and used together arbitrarily.

As the technology improves, more and more layers are stacked in a device to increase the bit density, enabling NAND flash memories with more storage capacity. It is noted that, due to the increment of density, NAND flash memories are more vulnerable to data retention issue. Valley search method is an effective method to solve the problem of data retention, which involves increasing or decreasing read voltage at a certain interval until an optimal value of a read voltage is found. However, conventional failure bit detection systems applied to valley search suffer from long settling time due to the heavy loading of failure bits and the multiple changes of the criteria code, which increases the time to find the final criteria code. Further, conventional failure bit detection systems are only able to detect a maximum failure bits number within a plurality of segments of memory cells of a memory device, rather than an actual failure bits number of each segment of memory cells of the memory device.

In this disclosure, a first voltage caused by a sensing current due to the failure bits is compared with a criteria voltage (e.g., a second voltage) to determine an actual failure bits number of each segment of memory cells of a memory device, rather than a maximum failure bits number within a plurality of segments of memory cells of the memory device. Further, a failure bits detection circuit for a next segment to be detected is pre-charged while a failure bits detection circuit for a current segment is changing a criteria code for the criteria voltage, thereby realizing a parallel operation. Therefore, the accuracy of the failure bits detection is improved and high speed performance without extra timing overhead is achieved. In this manner, 3D a NAND flash memory with high capacity and high performed may be achieved.

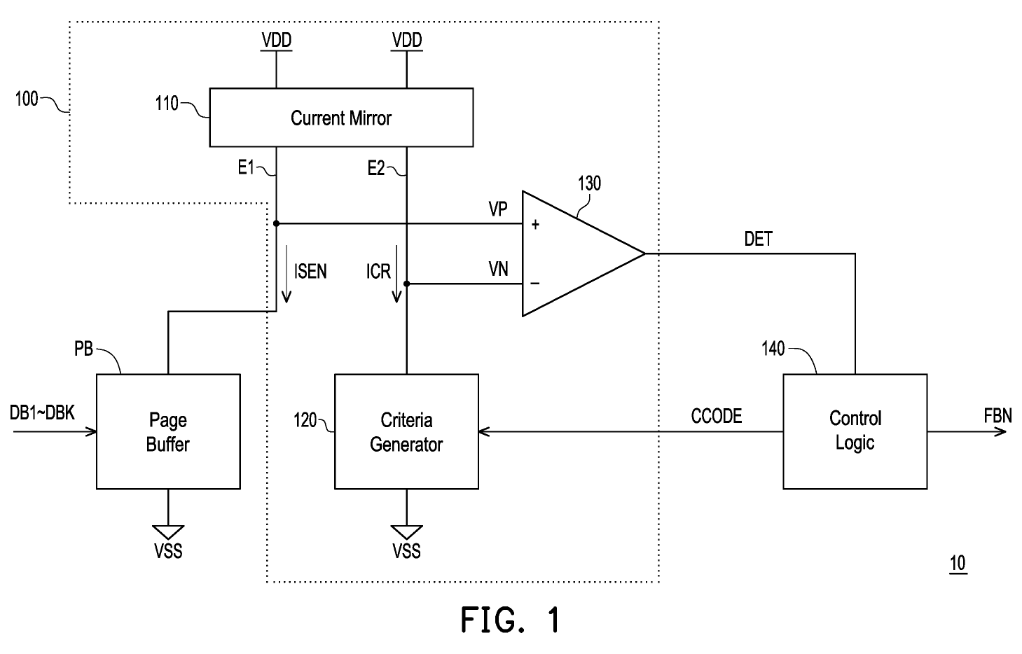

FIG. 1 is a schematic diagram of a memory device according to an embodiment of the disclosure. A memory device 10 includes a failure bits detection circuit 100, a control logic 140, and a page buffer PB. The failure bits detection circuit 100 includes a current mirror 110, a criteria generator 120, and a comparator 130. In one embodiment, the control logic 140 may be part of the failure bits detection circuit 100. In another embodiment, the control logic 140 may be an external element of the failure bits detection circuit 100. However, this disclosure is not limited thereto.

In one embodiment, the current mirror 110 includes a first end E1 coupled to the page buffer PB and a second end E2 coupled to the criteria generator 120. Further, the current mirror 110 is configured to receive a supply voltage VDD. Furthermore, the current mirror 110 is configured to mirror a sensing current ISEN at the first end E1 of the current mirror 110 to generate a criteria current ICR at the second end E2 of the current mirror 110 during a read mode of the memory device. The read mode is performed based on a valley search algorithm.

In one embodiment, the criteria generator 120 is configured to provide a criteria load between the second end E2 of the current mirror 110 and a reference ground end VSS according to a criteria code CCODE. That is, by changing the criteria code CCODE, the criteria load of the criteria generator 120 is changed, thereby adjusting a criteria voltage (i.e., a second voltage VN) provided by the criteria generator 120.

In one embodiment, the comparator 130 includes a first input end coupled to the first end E1 of the current mirror 110, a second input end coupled to the second end E2 of the current mirror 110, and an output end. For example, the first input end of the comparator 130 may be a positive input end, and the second input end of the comparator 130 may be a negative input end. Further, the comparator 130 is configured to compare a first voltage VP at the first input end with a second voltage VN (also known as a criteria voltage) at the second input end to generate a detection result DET at the output end for determining a failure bits number FBN of the memory device 10. It is worth mentioned that, the first voltage VP is determined by multiplying the sensing current ISEN by a page buffer load of the page buffer PB, and the page buffer load is determined based on the failure bits number of the memory device 10. In addition, the second voltage VN is determined by multiplying the criteria current ICR by the criteria load of the criteria generator 120.

Specifically, the page buffer PB is coupled to a segment of memory cells of the memory device 10. Further, the page buffer PB is coupled between the first end E1 of the current mirror 110 and the reference ground end VSS. The page buffer PB may receive failure bits information DB1~DBK. The failure bits information DB1~DBK may represent a failure bits number FBN (also known as failure bits count) in a memory segment. The page buffer PB may provide a page buffer load according to the failure bits information DB1~DBK. That is to say, the page buffer PB may be configured to receive the failure bits information DB1~DBK and provide the page buffer load between the first end E1 of the current mirror 110 and the reference ground end VSS according to the failure bits information DB1~DBK. Therefore, the page buffer PB may adjust a magnitude of the first voltage VP at the first end E1 of the current mirror 110 according to a level of the failure bits number FBN represented by the failure bits information DB1~DBK. Correspondingly, the comparator 130 may generate the detection result DET of the failure bit number FBN according to a comparison result of the first voltage VP and the second voltage VN.

In addition, the second voltage VN may be generated according to the criteria code CCODE. To be more specific, the criteria load of the criteria generator 120 is determined according to the criteria code CCODE. Further, by multiplying the criteria current ICR by the criteria load of the criteria generator 120, the second voltage VN is obtained. The criteria code CCODE may be a digital code of multiple bits, and may be provided by the control logic 140. The criteria code CCODE may be determined according to an objective failure bits number to be detected by the control logic 140.

For example, when the objective failure bits number is 5, four bits of the criteria code CCODE may be set as 0, 1, 0, and 1, respectively. In addition, when the failure bits information DB1~DBK indicates that an actual failure bit number FBN is greater than 5, the comparator 130 may generate the detection result DET equal to a logic value of 0. On the other hand, when the failure bits information DB1~DBK indicates that the actual failure bit number FBN is not greater than 5, the comparator 130 may generate the detection result DET equal to a logic value of 1. That is, in response to the first voltage VP being smaller than the second voltage VN, the detection result DET is configured to indicate that the failure bits number FBN is greater than the criteria code CCODE. On the other hand, in response to the first voltage VP being not smaller than the second voltage VN, the detection result DET is configured to indicate that the failure bits number FBN is not greater than the criteria code CCODE. However, this disclosure is not limited thereto.

That is to say, by changing criteria code CCODE to adjust the second voltage VN, the detection result DET may indicate the criteria code CCODE is closer to or away from an actual failure bits number FBN. For example, for an initial detection of the failure bits number FBN, the criteria code CCODE may be set as a middle number of a maximum allowable failure bits to detect an approximate magnitude of the actual failure bits number FBN. Then, while a current detection result DET indicates the failure bits number FBN is greater than a current criteria code CCODE, a next criteria code CCODE may increase to bring the criteria code CCODE closer to the actual failure bits number FBN. On the other hand, while a current detection result DET indicates the failure bits number FBN is not greater than a current criteria code CCODE, a next criteria code CCODE may decrease to bring the criteria code CCODE closer to the actual failure bits number FBN. Therefore, the actual failure bits number FBN may be obtained by successive approximation.

For example, the control logic 140 may be coupled between the output end of the comparator 130 and a control end of the criteria generator 120. Further, the control logic 140 may be configured to determine the criteria code CCODE and provide the criteria code CCODE to the criteria generator 120. Furthermore, the control logic 140 may be configured to: in response to the first voltage VP being smaller than the second voltage VN, increase the criteria code CCODE. On the other hand, the control logic 140 may be configured to: in response to the first voltage VP being not smaller than the second voltage VN, decrease the criteria code CCODE. In addition, in response to the criteria code CCODE being provide to the criteria generator 120 for a predetermined times (e.g., N times), determine the failure bits number FBN. However, this disclosure is not limited thereto.

In this manner, an actual failure bits number FBN of each segment of memory cells of the memory device 10 is obtained, rather than a maximum failure bits number within a plurality of segments of memory cells of the memory device 10. Therefore, the accuracy of the failure bits detection is improved.

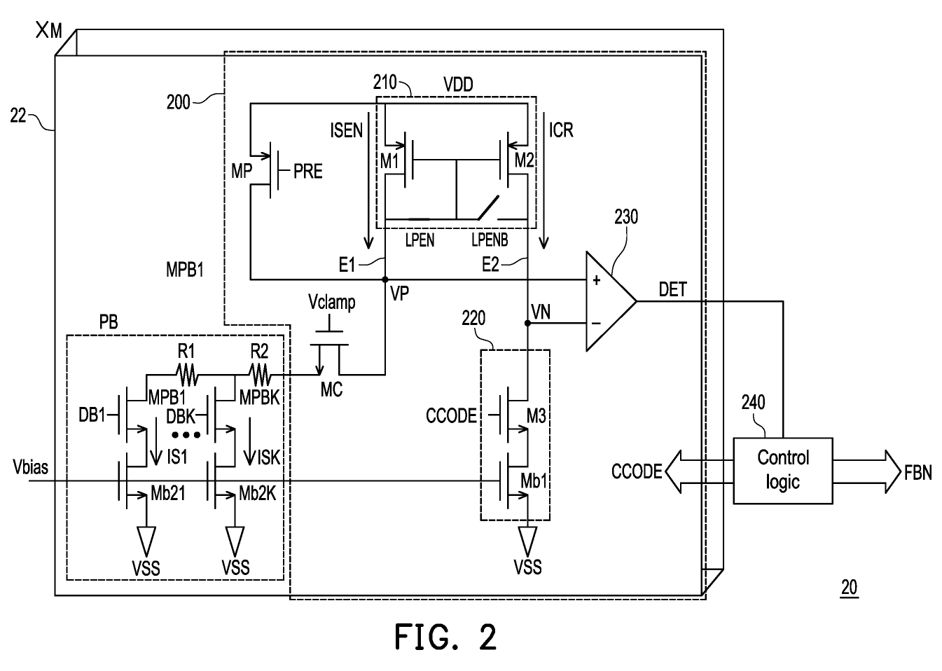

FIG. 2 is a schematic diagram of a memory device according to an embodiment of the disclosure. Referring to FIGS. 1 and 2, a memory device 20 in FIG. 2 is an exemplary embodiment of the memory device 10 in FIG. 1. For the sake of brevity, similar configurations and connections may be referred to the description of FIG. 1, while details are not redundantly described seriatim herein.

Reference is now made to FIG. 2. The memory device 20 includes a plurality of segments 22 of memory cells and a control logic 240. For example, the memory device 20 may include M segments 22 of memory cells as shown in FIG. 2, but this disclosure is not limited thereto. Each segment 22 may include a failure bits detection circuit 200 and a page buffer PB. The failure bits detection circuit 200 includes a current mirror 210, a criteria generator 220, a comparator 230, a pre-charge circuit MP, and a clamp transistor MC. In addition, the control logic 240 is coupled to the failure bits detection circuit 200 of each segment 22 of the memory cells of the memory device 20to detect the failure bits number FBN of each segment 22 of the memory cells of the memory device 20.

In one embodiment, the current mirror 210 includes a first transistor M1, a second transistor M2, a first switch LPEN, and a second switch LPENB. The first transistor M1 includes a first end configured to receive a supply voltage VDD, a second end coupled to the first end E1 of the current mirror 210, and a control end. The second end of the first transistor M1 is the first end E1 of the current mirror 210. The second transistor M2 includes a first end configured to receive the supply voltage VDD, a second end coupled to the second end E2 of the current mirror 210, and a control end. The second end of the second transistor M2 is the second end E2 of the current mirror 210. Wherein, the control end of the first transistor M1 is coupled to the control end of the second transistor M2. The first switch LPEN is coupled between the second end of the first transistor M1 and the control end of the first transistor M1. The second switch LPENB is coupled between the second end of the second transistor M2 and the control end of the second transistor M2.

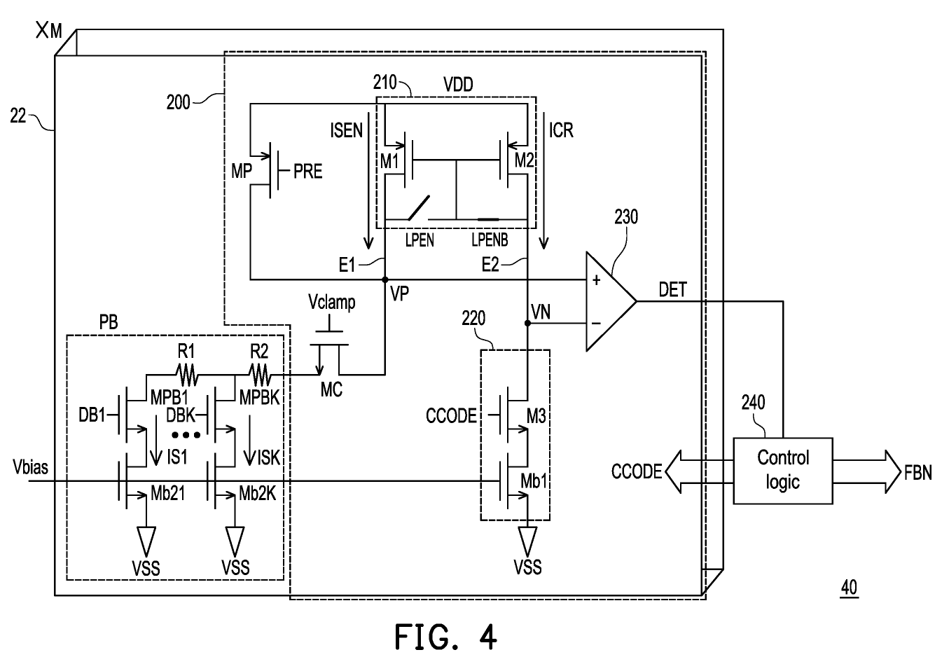

It is noted that, as shown in FIG. 2, during the read mode of the memory device 20, the first switch LPEN is configured to be turned on and the second switch LPENB is configured to be turn off. On the other hand, as shown in FIG. 4, during a program mode of the memory device 20, the first switch LPEN is configured to be turned off and the second switch LPENB is configured to be turn on. That is, during the read mode of the memory device 20, the current mirror 210 is configured to mirror the sensing current ISEN at the first end E1 of the current mirror 210 to generate the criteria current ICR at the second end E2 of the current mirror 210, thereby detecting the failure bit number FBN of the segment 22 of the memory cells. On the other hand, during the program mode of the memory device 20, the current mirror 210 is configured to mirror the criteria current ICR at the second end E2 of the current mirror 210 to generate the sensing current ISEN at the first end E1 of the current mirror 210, thereby programming the segment 22 of the memory cells. In this manner, the failure bits detection circuit 200 may provide different function during different modes of the memory device 20, thereby decreasing the need of the area overhead and achieving effect of power saving.

In one embodiment, the criteria generator 220 includes at least one first transistor M3 and a second transistor Mb1. The first transistor M3 includes a first end coupled to the second end E2 of the current mirror 210, and a control end configured to receive the criteria code CCODE. The second transistor Mb1 is coupled between a second end of the first transistor M3 and the reference ground end VSS through a first end and a second end of the second transistor Mb1, and controlled by a bias voltage Vbias through a control end of the second transistor Mb1. It is worth mentioned that, that a number of the first transistors M3 may be same as a number of bits of the criteria code CCODE, which may be one or more. However, this disclosure is not limited thereto.

In one embodiment, the comparator 230 may be implemented using an operational amplifier. Hardware architecture thereof is well known to those skilled in the art, and thus details are not redundantly described seriatim herein. The comparator 230 includes the first input end coupled to the second end of the second transistor M2 of the current mirror 210, the second input end coupled to the first end of the first transistor M1 of the criteria generator 220, and the output end.

In one embodiment, the page buffer PB includes a plurality of pull down transistors MPB1~MPBK and a plurality of bias transistors Mb21~Mb2K. The pull down transistors MPB1~MPBK are connected in series with the bias transistors Mb21~Mb2K respectively to form a plurality of transistor strings. The transistor strings are coupled to failure bits detection circuit 200 through a routing resistance R2. Further, the transistor strings are coupled in parallel between the routing resistance R2 and the reference ground end VSS through a routing resistance R1. Control ends of the pull down transistors MPB1~MPBK are configured to respectively receive the failure bits information DB1~DBK, and control ends of bias transistors Mb21~Mb2K are configured to collectively receive the bias voltage Vbias.

In this embodiment, taking the pull down transistor MPB1 as an example, when the failure bits information DB1 corresponding to the pull down transistor MPB1 is represented as a failure bit, the pull down transistor MPB1 may be turned on according to the failure bits information DB1, and may provide a pull down current IS1, so as to reduce a page buffer load provided by the page buffer PB. That is to say, when the failure bit number FBN represented by the failure bits information DB1~DBK exceeds a certain number, the page buffer load provided by the page buffer PB may be reduced to a certain value. In this way, the comparator 230 may have a comparison that the first voltage VP is smaller than the second voltage VN, and may generate the detection result DET of the logic value of 0.

In addition, in one embodiment, by disposing the clamp transistor MC between the page buffer PB and the first end E2 of the current mirror 210, an isolation effect may be generated between the page buffer PB with a relatively large load and the current mirror 210. For example, the clamp transistor MC is coupled between the page buffer PB and the first end E1 of the current mirror 210. Further, a control end of the clamp transistor MC may be configured to receive a bias voltage Vclamp and the bias voltage Vclamp may be smaller than the supply voltage VDD.

In addition, in one embodiment, the pre-charge circuit MP included a first end configured to receive the supply voltage, a second end coupled to the first end E1 of the current mirror 210, and a control end configured to receive a pre-charge signal PRE. Based on the supply voltage VDD, the pre-charge circuit MP is configured pre-charges the first end E1 of the current mirror 210 during a pre-charge period according to the pre-charge signal PRE. The pre-charge period may occur in an initial time interval of a failure bits detection operation of the failure bits detection circuit 200, and the first voltage VP may be quickly pulled up to be equal to the supply voltage VDD. For example, when the pre-charge signal PRE is a logic value of 0, the pre-charge circuit MP may be turned on, and a voltage at the first end E1 of the current mirror 210 is pulled up to the supply voltage VDD.

It is noted that, the control logic 240 is coupled to the failure bits detection circuit 200 of each segment 22 of the memory cells of the memory device 20 to detect the failure bits number FBN of each segment 22 of the memory cells of the memory device 20. For example, the failure bits detection circuits 200 may include a first failure bits detection circuit (e.g., the failure bits detection circuit 200) and a second failure bits detection circuit (e.g., an additional failure bits detection circuit 200). The first bit detection circuit may be coupled to a first page buffer of a first segment of the memory device 20 and the second bit detection circuit may be coupled to a second page buffer of a second segment of the memory device 20.

Further, during a pre-charge period of the second failure bits detection circuit, the control logic 240 may be configured to pre-charge the first end E1 of the current mirror 210 of the second failure bits detection circuit. Meanwhile, during the pre-charge period of the second failure bits detection circuit, the control logic 240 may be configured to change the criteria code CCODE of the first failure bits detection circuit. That is, in response to the first end E1 of the current mirror 210 of the second failure bits detection circuit being pre-charged, the control logic 240 may be configured to change the criteria code CCODE of the first failure bits detection circuit and provide the criteria code CCODE to the criteria generator 220 of the first failure bits detection circuit.

In other words, the failure bits detection circuit 200 for a next segment 22 to be detected is pre-charged while the failure bits detection circuit 200 for a current segment 22 is changing the criteria code CCODE, thereby realizing a parallel operation. In this manner, the accuracy of the failure bits detection is improved and high speed performance without extra timing overhead is achieved.

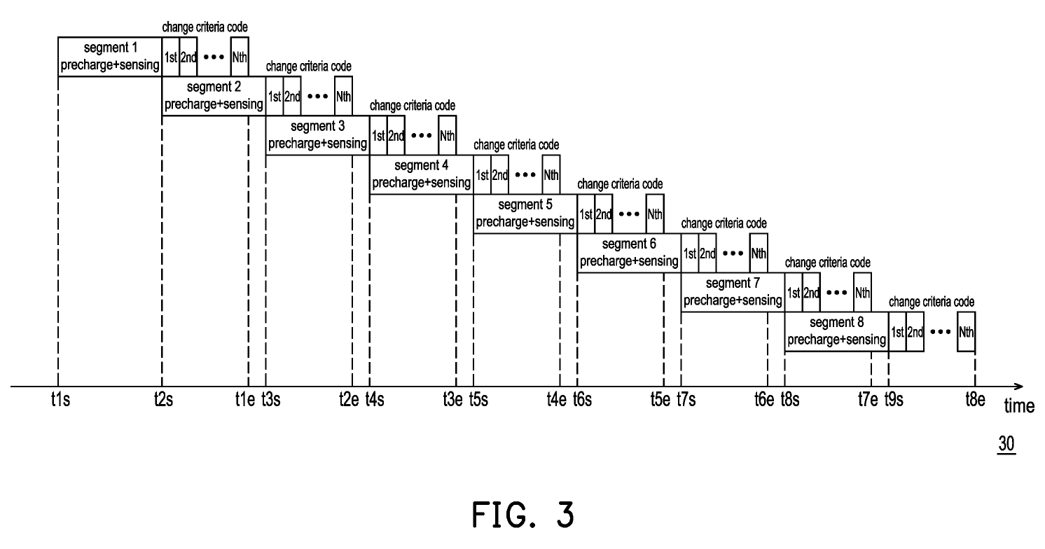

FIG. 3 is a schematic timing chart of a memory device according to an embodiment of the disclosure. Referring to FIGS. 2 and 3, a timing chart 30 depicts an order of failure bits detection operations of the plurality of segments 22 performed through the control logic 240 during the read mode of the memory device 20. In this embodiment, the memory device 20 include 8 segments 22 (e.g., segment 1~8). However, this disclosure is not limited thereto.

In one embodiment, at a time t1s, the control logic 240 is configured to pre-charge the failure bits detection circuit 200 of the segment 1 and sense the first voltage induced by the sensing current ISEN of the segment 1. In a time t2s, the control logic 240 is configured to change the criteria code CCODE of the segment 1 for N times to determine an actual failure bits number FBN of the segment 1. In a time t1e, after N times of changing the criteria code, the control logic 240 is configured to generate the failure bit number FBN. Also, in the time t2s, the control logic 240 is configured to pre-charge the failure bits detection circuit 200 of the segment 2 and sense the first voltage induced by the sensing current ISEN of the segment 2. That is, during a pre-charge mode of the segment 2, the criteria code CCODE of the segment 1 is keep change to determine the failure bits number FBN of the segment 1, thereby realizing a parallel operation.

Similarly, at a time t3s to a time t8e as shown in FIG. 3, pre-charging of segments 3~8 is performed while the criteria code CCODE of the segment 2~7 are changing, respectively. For the sake of brevity, similar details of these operations may be referred to the description of the segment 1 and the segment 2, while details are not redundantly described seriatim herein.

FIG. 4 is a schematic diagram of a memory device according to an embodiment of the disclosure. Referring to FIGS. 2 and 4, a memory device 40 in FIG. 4 is similar as the memory device 20 in FIG. 2. The difference is that the memory device 20 is in the read mode and the memory device 40 is in the program mode.

Specifically, instead of turning on the first switch LPEN and turning off the second switch LPENB, the first switch LPEN is turned off and the second switch LPENB is turned on. That is, instead of mirroring the sensing current ISEN to generate the criteria current ICR to detect the failure bit number FBN of the segment 22 of the memory cells, the current mirror 110 is configured to mirror the criteria current ICR to generate the sensing current ISEN for detecting the failure bit number FBN of the segment 22 of the memory cells after programming, thereby determining whether data is corrected is programmed into the segment 22 of the memory cells or not.

In this manner, the failure bits detection circuit 200 may provide different function during different modes of the memory device 40, thereby decreasing the need of the area overhead and achieving effect of power saving.

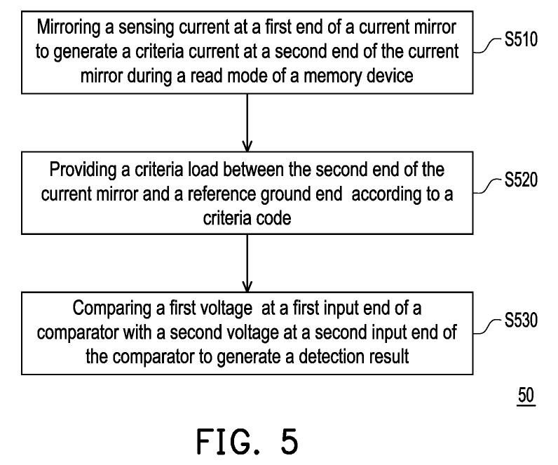

FIG. 5 is a schematic flowchart of a failure bits detection method according to an embodiment of the disclosure. Referring to FIGS. 1 and 5, a failure bits detection method 50 includes steps S510~S530.

In the step S510, the sensing current ISEN at the first end E1 of the current mirror 110 is mirrored to generate the criteria current ICR at the second end E2 of the current mirror 110 during a read mode of a memory device 10. Further, the first end E1 of the current mirror 110 is coupled to the page buffer PB of the memory device 10 and the second end E2 of the current mirror 110 is coupled to the criteria generator 120. In the step S520, a criteria load is provided between the second end E2 of the current mirror 110 and the reference ground end VSS according to the criteria code CCODE. In the step S530, the first voltage VP at the first input end of the comparator 130 is compared with the second voltage VN at the second input end of the comparator 130 (and after the criteria code CCODE has been changed for N times) to generate the detection result for determining a failure bits number FBN of the memory device.

In addition, the implementation details of the failure bits detection method 50 may be referred to the descriptions of FIGS. 1-4 to obtain sufficient teachings, suggestions, and implementation embodiments, while the details are not redundantly described seriatim herein.

In summary, according to the failure bits detection circuit, the failure bits detection circuit method, and the memory device, an actual failure bits number of each segment of memory cells of a memory device is obtained. Further, a failure bits detection circuit for a next segment to be detected is pre-charged while a failure bits detection circuit for a current segment is changing a criteria code for the criteria voltage, thereby realizing a parallel operation. Therefore, the accuracy of the failure bits detection is improved and high speed performance without extra timing overhead is achieved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A failure bits detection circuit, comprising:
a current mirror, comprising a first end coupled to a page buffer of a memory device and a second end coupled to a criteria generator, and configured to:
mirror a sensing current at the first end of the current mirror to generate a criteria current at the second end of the current mirror during a read mode of the memory device;
the criteria generator, configured to:
provide a criteria load between the second end of the current mirror and a reference ground end according to a criteria code; and
a comparator, comprising a first input end coupled to the first end of the current mirror, a second input end coupled to the second end of the current mirror, and an output end, and configured to:
compare a first voltage at the first input end with a second voltage at the second input end to generate a detection result at the output end for determining a failure bits number of the memory device.

2. The failure bits detection circuit according to claim 1, wherein
the read mode is performed based on a valley search algorithm.

3. The failure bits detection circuit according to claim 1, wherein
in response to the first voltage being smaller than the second voltage, the detection result is configured to indicate that the failure bits number is greater than the criteria code; and
in response to the first voltage being not smaller than the second voltage, the detection result is configured to indicate that the failure bits number is not greater than the criteria code.

4. The failure bits detection circuit according to claim 1, further comprising:
a control logic, coupled between the output end of the comparator and a control end of the criteria generator, and configured to:
determine the criteria code and provide the criteria code to the criteria generator; and
in response to the criteria code being provide to the criteria generator for a predetermined times, determine the failure bits number.

5. The failure bits detection circuit according to claim 4, wherein
the control logic is further configured to:
in response to the first voltage being smaller than the second voltage, increase the criteria code; and
in response to the first voltage being not smaller than the second voltage, decrease the criteria code.

6. The failure bits detection circuit according to claim 4, wherein
the failure bits detection circuit is coupled to a first page buffer of a first segment of the memory device,
an additional failure bits detection circuit is coupled to a second page buffer of a second segment of the memory device, and
the control logic is further configured to:
pre-charge a first end of a current mirror of the additional failure bits detection circuit; and
in response to the first end of the current mirror of the additional failure bits detection circuit being pre-charged, change the criteria code of the failure bits detection circuit and provide the criteria code to the criteria generator of the failure bits detection circuit.

7. The failure bits detection circuit according to claim 1, wherein
the first voltage is determined by multiplying the sensing current by a page buffer load of the page buffer, and the page buffer load is determined based on the failure bits number of the memory device.

8. The failure bits detection circuit according to claim 1, wherein
the second voltage is determined by multiplying the criteria current by the criteria load.

9. The failure bits detection circuit according to claim 1, wherein
the current mirror is further configured to:
mirror the criteria current at the second end of the current mirror to generate the sensing current at the first end of the current mirror during a program mode of the memory device.

10. The failure bits detection circuit according to claim 1, wherein
the current mirror further comprises:
a first transistor, comprising a first end configured to receive a supply voltage, a second end coupled to the first end of the current mirror, and a control end;
a second transistor, comprising a first end configured to receive the supply voltage, a second end coupled to the second end of the current mirror, and a control end, wherein the control end of the first transistor is coupled to the control end of the second transistor;
a first switch, coupled between the second end of the first transistor and the control end of the first transistor; and
a second switch, coupled between the second end of the second transistor and the control end of the second transistor.

11. The failure bits detection circuit according to claim 10, wherein
during the read mode of the memory device, the first switch is configured to be turned on and the second switch is configured to be turn off, and
during a program mode of the memory device, the first switch is configured to be turned off and the second switch is configured to be turn on.

12. The failure bits detection circuit according to claim 1, wherein the criteria generator comprises:
at least one first transistor, comprising a first end coupled to the second end of the current mirror and a control end configured to receive the criteria code; and
a second transistor, coupled between a second end of the at least one first transistor and the reference ground end, and controlled by a bias voltage.

13. The failure bits detection circuit according to claim 1, further comprising:
a pre-charge circuit, coupled to the first end of the current mirror, and configured to pre-charge the first end of the current mirror according to a pre-charge signal during a pre-charge period.

14. The failure bits detection circuit according to claim 1, further comprising:
a clamp transistor, coupled between the page buffer and the first end of the current mirror.

15. The failure bits detection circuit according to claim 1, wherein
the page buffer is configured to:
receive failure bits information, and
provide a page buffer load between the first end of the current mirror and the reference ground end according to the failure bits information.

16. A failure bits detection method, comprising:
mirroring a sensing current at a first end of a current mirror to generate a criteria current at a second end of the current mirror during a read mode of a memory device, wherein the first end of the current mirror is coupled to a page buffer of the memory device and the second end of the current mirror is coupled to a criteria generator;
providing a criteria load between the second end of the current mirror and a reference ground end according to a criteria code; and
comparing a first voltage at a first input end of a comparator with a second voltage at a second input end of the comparator to generate a detection result for determining a failure bits number of the memory device.

17. The failure bits detection method according to claim 16, wherein
the read mode is performed based on a valley search algorithm.

18. The failure bits detection method according to claim 16, wherein
in response to the first voltage being smaller than the second voltage, the detection result is configured to indicate that the failure bits number is greater than the criteria code; and
in response to the first voltage being not smaller than the second voltage, the detection result is configured to indicate that the failure bits number is not greater than the criteria code.

19. A memory device, comprising:
a plurality of segments of memory cells, wherein each of the plurality of segments comprises a page buffer; and
a plurality of failure bits detection circuits, wherein each of the plurality of failure bits detection circuits is coupled to the page buffer, respectively, and comprises:
a current mirror, comprising a first end coupled to the page buffer of a memory device and a second end coupled to a criteria generator, and configured to:
mirror a sensing current at the first end of the current mirror to generate a criteria current at the second end of the current mirror during the read mode of the memory device; and
the criteria generator, configured to:
provide a criteria load between the second end of the current mirror and a reference ground end according to a criteria code; and
a comparator, comprising a first input end coupled to the first end of the current mirror, a second input end coupled to the second end of the current mirror, and an output end, and configured to:
compare a first voltage at the first input end with a second voltage at the second input end to generate a detection result at the output end for determining a failure bits number of the memory device.

20. The memory device according to claim 19, wherein
the plurality of failure bits detection circuit comprises a first failure bits detection circuit and a second failure bits detection circuit, and
the memory device further comprises:
a control logic, coupled to the plurality of failure bits detection circuits, and configured to:
pre-charge the first end of the current mirror of the second failure bits detection circuit; and
in response to the first end of the current mirror of the second failure bits detection circuit being pre-charged, change the criteria code of the first failure bits detection circuit and provide the criteria code to the criteria generator of the first failure bits detection circuit.
